(19) United States
(12) Patent Application Publication
(10) Pub. No.: US 2006/0238219 A1
(43) Pub. Date: Oct. 26, 2006

(54) Signal level shifting bus switch

(75) Inventor: Akira Takiba, Kawasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/405,424

(22) Filed: Apr. 18, 2006

(30) Foreign Application Priority Data
Apr. 19, 2005 (JP) 2005-120919

(51) Int. Cl. H03L 5/00

(52) U.S. Cl. 326/63; 327/333

(57) ABSTRACT

A signal level shifting bus switch is connected between a first semiconductor device driven by a first supply voltage VccA having a first difference from a reference voltage and a second semiconductor device driven by a second supply voltage VccB having a second difference, less than the first difference, from the reference voltage, and comprises a first I/O terminal for inputting/outputting the first supply voltage; a second I/O terminal for inputting/outputting the second supply voltage; and a control terminal provided to receive a control voltage. The signal level shifting bus switch further comprises: a first transistor with a gate driven by a control signal of the first supply voltage; a second transistor with a gate driven by a control signal of the second supply voltage, the first and second transistors being connected between the first and second I/O terminals; and an absolute value of a threshold voltage of the second transistor being less than an absolute value of a threshold voltage of the first transistor.

### CROSS-REFERENCE TO RELATED APPLICATION

The present application is based upon and claims the benefit of priority from Japanese Patent Application No. 2005-120919, filed on Apr. 19, 2005, the entire content of which is incorporated herein by reference.

### BACKGROUND

Recently, there is increasingly employed a lower supply voltage to Central Processing Units (CPU) or Application Specified Integrated Circuits (ASIC) for changes in process used and for low total power consumption. Under the existing conditions in conventional systems or in systems dealing with analog signals, it is impossible to realize the lower supply voltage and it is difficult to directly input signals as input signal to CPU or ASIC. Accordingly, it is necessary to provide a signal level shifter that can shift a signal level between two different levels of supply voltage each driving different systems.

As an example of a system which is driven by the different supply voltages, there is a system driven by a voltage level shifting from 5V to 3.3V. The 5V supply voltage is frequently used in the conventional systems or the systems dealing with analog signals, while the 3.3V supply voltage level is increasingly used in newly introduced CPU or ASIC. In such cases, a signal is supplied from 5V system through a signal level shifter to 3.3V system of CPU, and a signal is supplied from an analog system driven by 5V through a signal level shifter to 3.3V system of ASIC.

Along with a reduction in voltage level used by CPUs or the like, systems that require signal level shifting from 5V to 2.5V or from 3.3V to 2.5V are gradually growing. In this case, too, a signal level shifter, such as a signal level shifting switch, connected between two systems driven by 3.3V and 2.5V, respectively, provides a signal that has a voltage level given by voltage level shifting from a supply voltage level to one of the systems from the other.

### SUMMARY

A signal level shifting bus switch according to an embodiment of the present invention, connected between a first semiconductor device driven by a first supply voltage having a first difference from a reference voltage and a second semiconductor device driven by a second supply voltage having a second difference, less than the first difference, from the reference voltage, and the signal level shifting bus switch comprises a first terminal configured to input/output the first supply voltage; a second terminal configured to input/output the second supply voltage; a control terminal configure to receive a control voltage; a first transistor with a gate driven by a control signal of the first supply voltage; a second transistor with a gate driven by a control signal of the second supply voltage, the first and second transistors being connected between the first and second terminals; and an absolute value of a threshold voltage of the second transistor being less than an absolute value of a threshold voltage of the first transistor.

### BRIEF DESCRIPTION OF THE DRAWINGS

FIG. 1 is a block diagram showing the constitution of a first embodiment of a signal level shifting bus switch;

FIG. 2 is a circuit diagram showing the constitution of a second embodiment of a signal level shifting bus switch;

FIG. 3 is a characteristic graph showing the relationship of an input and output voltage according to the second embodiment;

FIG. 4A is a schematic plan view showing the layout of the conventional art, and FIG. 4B is a schematic plan view showing the layout of the second embodiment;

FIG. 5 is a circuit diagram showing the constitution of a third embodiment of a signal level shifting bus switch;

FIG. 6 is a circuit diagram showing the constitution of a fourth embodiment of a signal level shifting bus switch; and

FIG. 7 is a circuit diagram showing the constitution of a fifth embodiment of a signal level shifting bus switch.

### DETAILED DESCRIPTION OF THE INVENTION

Referring to the accompanying drawings, the embodiments of a signal level shifting switch are described in detail.

### First Embodiment

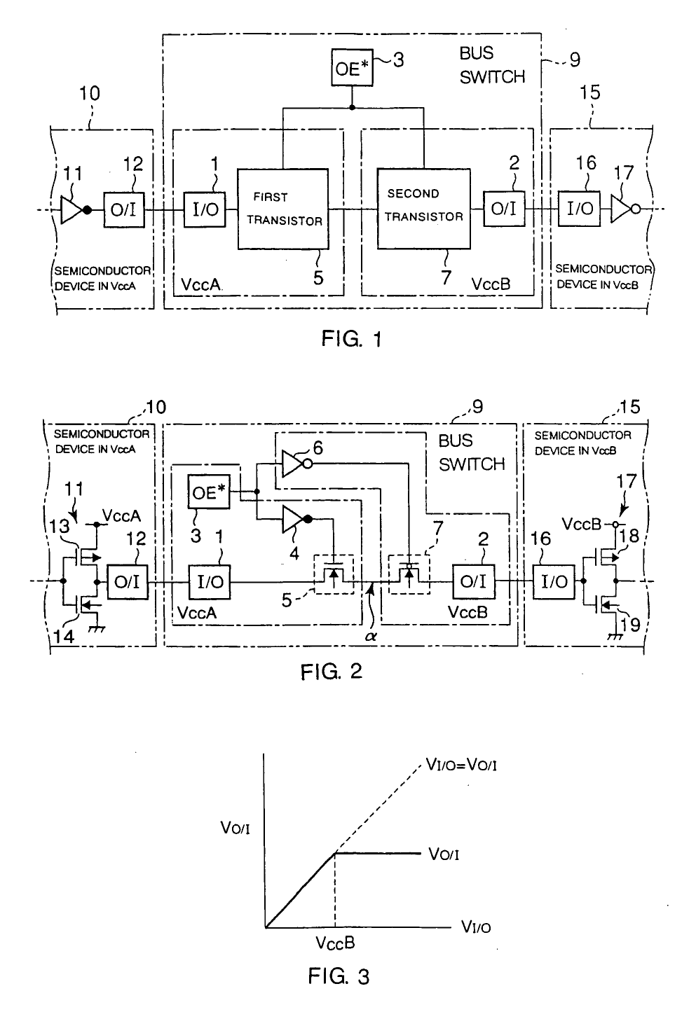

As shown in FIG. 1, the first embodiment of a signal level shifting bus switch 9 is provided in a logical circuit that includes a first terminal 1 for inputting/outputting a first supply voltage VccA having a first difference from a reference voltage, a second terminal 2 for outputting/inputting a second supply voltage VccB having a second difference, less than the first difference, from the reference voltage, and a control terminal 3 provided to receive a control voltage OE*. Between the first terminal 1 and second terminal 2, there are provided a first transistor 5 with a gate driven by a control signal of the first supply voltage VccA and a second transistor 7 with a gate driven by a control signal of the second supply voltage VccB. The first and second transistors 5 and 7 are set such that an absolute value of a threshold voltage of the second transistor 7 is less than an absolute value of a threshold voltage of the first transistor 5.

The first and second transistors 5 and 7 are metal oxide semiconductor (MOS) transistors, and, with regard to conductivity type, may be n-channel MOS transistors or p-channel MOS transistors. In case that the first and second transistors 5 and 7 may be n-channel transistors, an absolute value of the threshold voltage of the second transistor 7 is set less than an absolute value of the threshold voltage of the first transistor 5. For example, the first transistor 5 is an n-channel E-type transistor with a gate to which a control voltage of 5V may be applied, and the second transistor 7 is an n-channel I-type transistor with 3.3V as its gate potential and 0V as its threshold voltage Vth.

In case of that the first and second transistor 5 and 7 may be p-channel transistors, the threshold voltage of the second transistor 7 is set greater than the threshold voltage of the first transistor 5. For example, the first transistor 5 is a p-channel E-type transistor with a gate to which a control voltage of −5V may be applied, and the second transistor 7 is a p-channel I-type transistor with −3.3V as its gate potential and 0V as its threshold voltage Vth. This embodiment may be readily understood more concretely in details later from description on the second to fifth embodiments.

### Second Embodiment

According to the second embodiment of a signal level shifting switch 9 shown in FIG. 2, the first transistor 5 of the first embodiment shown in FIG. 1 is an n-channel E-type MOS transistor, and the second transistor 7 is an n-channel I-type MOS transistor. A control signal OE* inputted from a control terminal 3 is supplied to an inverter 4 of the VccA system, and is converted into a VccA control signal, which is supplied to the gate of the first transistor 5. The control signal OE* is supplied also to an inverter 6 of a VccB system and converted into a VccB control signal, which is supplied to the gate of the second transistor 7.

As shown in FIG. 2, the signal level shifting switch according to the second embodiment employs a series connection of the n-channel E-type transistor switch 5 and the n-channel I-type transistor switch 7. The n-channel I-type transistor switch 7, which is a transistor has its threshold voltage set to 0V, is closed (ON) between its source and drain when the gate source voltage Vgs is 0V. The n-channel E-type transistor switch 5 is connected to the inverter 4, which represents a control circuit driven by the first supply voltage VccA. The n-channel I-type transistor switch 7 is connected to the inverter 6, which represents a control circuit driven by the second supply voltage VccB. The n-channel E-type and I-type transistor switches 5 and 7 are controlled by the two different VccA and VccB control signals, which have different voltage levels.

For voltage level shifting from 5V to 3.3V, the first supply voltage VccA is set at 5V and the second supply voltage VccB at 3.3V. Under this condition, when the control signal OE* is at a low (L) level, OE*=L, the VccA control signal is at 5V and the VccB control signal is at 3.3V. The control voltage 5V is applied to the gate of the n-channel E-type transistor switch 5, and the control voltage 3.3V is applied to the gate of the n-channel I-type transistor switch 7. Assuming that the threshold voltage Vth of the n-channel E-type transistor switch 5 is 1V, when an input signal H having a voltage level of 5V is applied to the first input/output (I/O) terminal 1, the source voltage is 5V and the drain voltage of the n-channel E-type transistor switch 5 appears at a node □. The voltage at the node □ is 4V that is given by subtracting the threshold voltage (1V) from the source voltage (5V), 5V−1V=4V.

Next, since the n-channel I-type transistor switch 7 is open (OFF) between its source and drain when the gate source Vgs (in this case, a difference in voltage between the gate and node □) is 0V and its gate potential is at 3.3V, a potential at the second output/input (O/I) terminal 2, where the drain voltage of the n-channel I-type transistor switch 7 appears, cannot exceed a potential of the gate. Thus, the potential at the second output/input (O/I) terminal 2 cannot rise in excess of the potential (3.3V) of the gate of the n-channel I-type transistor 7. In this manner, signal level shifting from 5V to 3.3V is possible.

When a signal L is applied to the first I/O terminal 1, both n-channel E-type and I-type transistor switches 5 and 7 are open (OFF) because their gate potentials are higher than the potential at the first I/O terminal 1 more than the threshold voltage Vth is, ensuring the signal L to appear at the second O/I terminal 2. FIG. 3 shows the relationship between the input voltage to the first I/O terminal 1 and the output voltage from the second O/I terminal 2. The output voltage at the second O/I terminal 2 is proportional to the input voltage at the first I/O terminal 1 as long as the input voltage is lower than or equal to a voltage level of the second supply voltage VccB (a desired voltage level at the second O/I terminal 2=the gate voltage of the n-channel I-type transistor switch 7), and clamped at the level of VccB after the input voltage has exceeded the level of VccB.

The above-mentioned relationship shown in FIG. 3 is the same relationship given by the conventional circuit using a single n-channel I-type transistor switch. However, the second embodiment has solved the leakage current problem when the switch is open (OFF) due to the fluctuation of threshold voltage Vth by connecting the n-channel E-type transistor switch in series with the n-channel I-type transistor switch. The problem has been solved by the n-channel E-type transistor switch that ensures open between the I/O and O/I terminals when the n-channel I-type transistor switch remains inadvertently closed (ON).

The second embodiment can solve the problem encountered in the conventional circuit not only during level shifting from the high 5V to 3.3, but also during shifting from 5V to 2.5V. In the latter case, the second supply voltage VccB is set at 2.5V, with the first supply voltage VccA left at 5V. The n-channel E-type transistor switch 5 is connected to the control circuit 4 driven by 5V, and the n-channel I-type transistor switch is connected to the control circuit 6 driven by 2.5V. They are activated under control of different voltages.

When, now, OE*=L, voltage 5V is applied to the gate of the n-channel E-type transistor switch 5, and voltage 3.3V is applied to the gate of the n-channel I-type transistor switch 7. Assuming that the threshold voltage Vth of the n-channel E-type transistor switch 5 is 1V, when voltage 5V is applied to the first input/output (I/O) terminal 1, voltage appearing at the node □ (see FIG. 1) is 4V that is given by subtracting the threshold voltage (1V) from the source voltage (5V), 5V−1V=4V.

Next, since the n-channel I-type transistor switch 7 is open (OFF) between its source and drain when the gate source Vgs (in this case, a difference in voltage between the gate and node □ is 0V and its gate potential is at 2.5V, a potential at the second output/input (O/I) terminal 2 cannot rise in excess of the potential (2.5V) of the gate of the n-channel I-type transistor 7. In this manner, signal level shifting from 5V to 2.5V is possible.

When a signal L is applied to the first I/O terminal 1, both n-channel E-type and I-type transistor switches 5 and 7 are open (OFF) because their gate potentials are higher than the potential at the first I/O terminal 1 more than the threshold voltage Vth is, ensuring the signal L to appear at the second O/I terminal 2. That is, the output appearing at the second O/I terminal 2 will not be clamped at the source voltage VccB on the side of second O/I terminal 2, preventing damage on the circuit element in the subsequent next stage, for example, a second semiconductor device 15 driven by VccB, by eliminating the possibility that a high voltage might be applied to the circuit element connected to the second O/I terminal 2.

Even if the threshold voltage Vth of the n-channel I-type transistor 7 fluctuates to the minus side, the n-channel E-type transistor 5 turns off the bus switch, making it possible to set the threshold voltage Vth at 0V. In this case, even if the threshold voltage Vth has fluctuated to the plus side (+0.2V), it impossible to provide the output signal having a voltage level high enough for the circuit element in the next subsequent stage to recognize the H level out of the output signal.

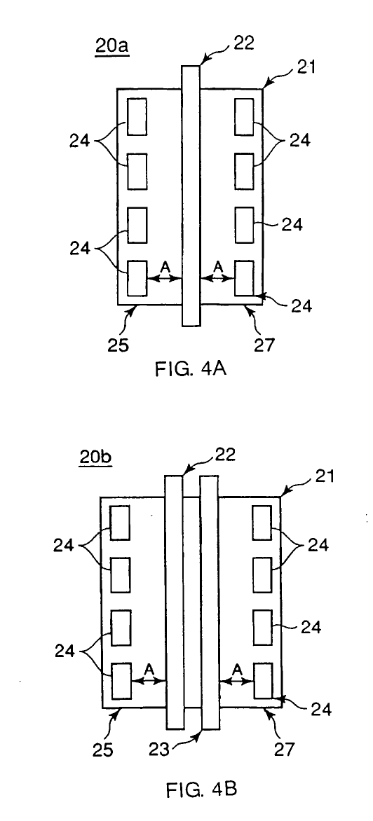

According to the second embodiment, addition of the n-channel I-type transistor to the n-channel E-type transistor might need such a wide area as to require an increase in chip size. For comparison, FIG. 4A shows a layout 20a of the conventional example, and FIG. 4B shows a layout 20b according to the second embodiment.

As shown in FIG. 4A, the conventional layout 20a illustrates, on N+ transistor region (diffusion layer) 21, a column of polycrystalline silicon gates (Gate Poly) 22 for E-type transistors and contact holes 24 for external connection, but fails to illustrate metal layer. Viewing in FIG. 4A, the contact holes 24 in a column on the left side of the column of silicon gates 22 are formed for connection with I/O terminals on one side 25, and the contact holes 24 in a column on the right side of the column of silicon gates 22 are formed for connection with O/I terminals on the other side 27. The left column of the contact holes 24 is spaced from the silicon gates 22 by a distance A. By the same distance A, the right column of the contact holes 24 is spaced from the column of silicon gates 22.

Referring to FIG. 4B, the second embodiment includes the I-type transistors connected in series with the E-type transistors, respectively. Viewing in FIG. 4B, the column of polycrystalline silicon gates 22 for E-type transistors and construction portion on the left side of it correspond exactly to their counterparts in the conventional layout 20a. However, a layout 20b shown in FIG. 4B differs from the conventional layout 20b in addition of I-type transistors on the right side. In detail, a column of polycrystalline silicon gates 23 for the I-type transistors is arranged in parallel to the column of polycrystalline silicon gates 22. The right column of contact holes 24 is spaced from this column of polycrystalline silicon gates 23 by the same distance A.

As is readily seen from FIG. 4B, despite the fact that the I-type transistors are added as arranged in parallel to the E-type transistors, since the columns of polycrystalline silicon gates 23 and 22 for I-type and E-type transistors are arranged very closely to realize the illustrated layout 20b, an increase in area for transistors is accomplished by area portions for the single column of polycrystalline silicon gates and for the distance between the two columns of polycrystalline silicon gates, making it possible to suppress a proportion of this increase to the total area to the minimum as opposed to prospect that using two kinds of transistors might double the installation area for the transistors.

Usually, in view of protection from electrostatic discharge (ESD), a distance A of contact holes from the column of crystalline silicon gates is increased in the case of transistors to be connected to the I/O and O/I terminals 1 and 2 involving input and output pins because these transistors need to be spaced remoter from the columns of crystalline silicon gates more than the logic forming transistors are, making the above-mentioned proportion small.

### Third Embodiment

In the above-described second embodiment, even though the control signal OE* is fed via the control terminal 3 driven by the first supply voltage VccA and the control signal OE* is inverted at the inverters 4 and 6 and applied to the gates of the n-channel E-type and I-type transistors 5 and 7, the control signal OE* may have a voltage level of the second supply voltage VccB.

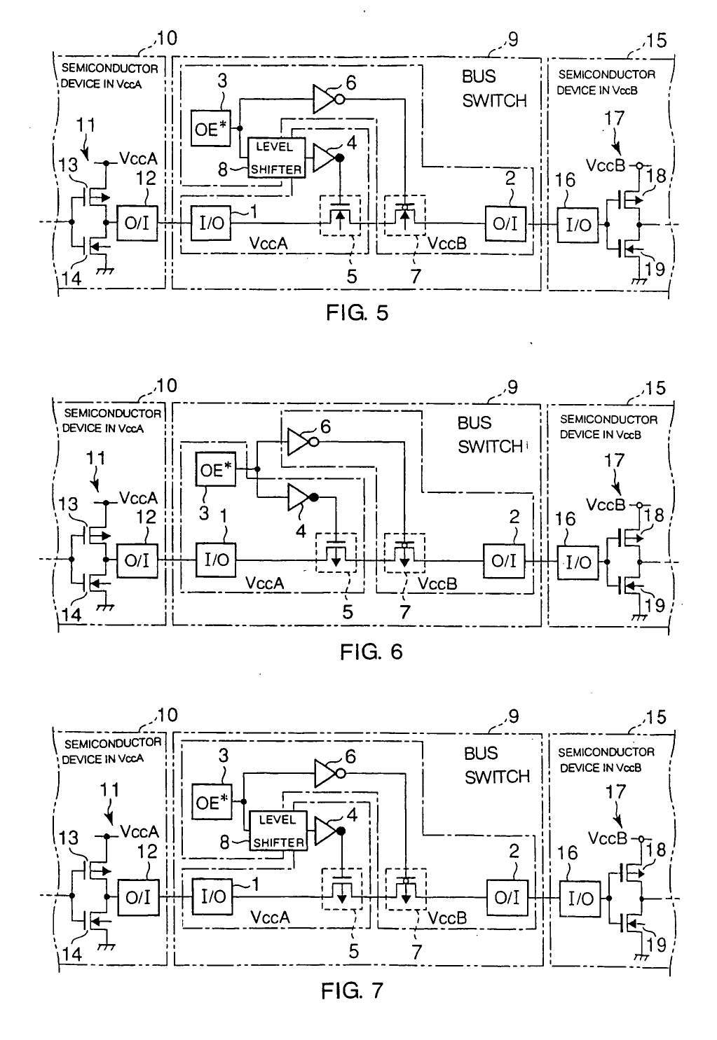

In this case, as taught by the third embodiment illustrated in FIG. 5, there may be conceived a circuit in which a level shifter 8 is interposed between the control terminal 3, to which a control signal OE* is fed, and an inverter 4, which represents a control circuit for an n-channel E-type transistor 5. According to this construction, the second supply voltage VccB on the side of a second O/I terminal is used to provide a control signal OE* as different from the second embodiment in which the first supply voltage VccA on the side of the first I/O terminal is used to produce the control signal OE*.

### Fourth Embodiment

In the preceding second and third embodiments, the n-channel transistors were used. The present proposal is not limited to the use of such n-channel transistors. The present proposal may be implemented by using p-channel MOS transistors as taught by the fourth embodiment.

FIG. 6 is a circuit diagram showing constitution of the fourth embodiment of a signal level shifting bus switch. Throughout each of FIG. 6 and FIGS. 1, 2 and 5, like reference numerals are used to designate like or similar elements or portions. In the fourth embodiment, a first transistor 5 is a p-channel E-type transistor, and a second transistor 7 a p-channel I-type transistor. When the p-channel transistors are used, a first supply voltage VccA is, for example, −5V, and a second supply voltage VccB is, for example, −3.3V or −2.5V. Assuming a reference voltage at 0V, the first supply voltage VccA differs from the reference voltage in absolute value by 5V, the second supply voltage VccB is differs from the reference voltage in absolute value by 3.3V or 2.5V. This fourth embodiment has the same relation as each of the second and third embodiments in that the voltage VccB is between the reference voltage and the voltage VccA.

The operation of this fourth embodiment is substantially the same as that of the third embodiment except that the voltage values are minus values in the fourth embodiment. Describing in detail, when the control signal OE*=L, the voltage −5V is applied to the gate of the p-channel E-type transistor switch 5, and the voltage −2.5 applied to the gate of the p-channel I-type transistor switch 7. Assuming that the threshold voltage of the p-channel E-type transistor switch 5 is −1V, when −5V signal is applied to a first I/O terminal 1, the drain voltage −4V of the p-channel E-type transistor switch 5 appears at a node between the p-channel E-type and I-type transistor switches 5 and 7 (see FIG. 6). The drain voltage at the node is given by −4V=−5V−(−1V).

Then, voltage −2.5V is applied to the gate of the p-channel I-type transistor switch 7. Because the p-channel I-type transistor switch 7 is open (OFF) between its source and drain when the gate source voltage Vgs is 0V, an output potential at a second O/I terminal 2 cannot drop below the gate potential (−2.5V) and will be clamped at the gate potential of the p-channel I-type transistor switch 7. In this manner, it is possible to shift a signal level from −5V to −2.5V.

### Fifth Embodiment

In the above mentioned fourth embodiment, the control signal OE* is dependent on the first supply voltage VccA. Similarly to the third embodiment, a control signal OE* may be produced using the second supply voltage VccB, which has a voltage value of −3.3V or −2.5V. As taught by the fifth embodiment illustrated in FIG. 7, a level shifter 8 is connected between an input terminal 3, to which a control signal OE* is applied.

When the control signal OE* is, for example, at −2.5V, the level shifter level shifts this control signal down to a voltage level of −5V, which is inverted at an inverter 4. The inverted signal from the inverter 4 is applied to the gate of a p-channel E-type transistor 5. The other operation is substantially the same as that of the third embodiment. Thus further description is omitted for the sake of brevity.

According to each of the preceding embodiments, signal level shifting from a voltage level of an input signal to a desired voltage level of an output signal is possible even if the input signal applied to the first input/output terminal is of a first supply voltage and the output signal is required to be of the second supply voltage, for example, a middle voltage level of or a low voltage level of because a first transistor, to the gate of which a control signal of the first supply voltage differing greatly in absolute value from a reference voltage is applied, is an E-type transistor having a predetermined voltage value as its threshold, and a second transistor is an I-type transistor having the threshold voltage of a voltage value, for example 0V, less than the threshold voltage of the first transistor.

Besides, efficient signal level shifting is possible with reduced chip size without relying on the circuit structure using complicated logical circuits. As compared to the signal level shifting using, as a signal level shifting element, a single transistor, a superior signal level shifting is possible by providing the gate of an I-type transistor in parallel with the gate of the existing E-type transistor with a small in crease in area needed to allow installation of two gates in parallel against the prospect that using two transistors might double area for their installation.

1. A signal level shifting bus switch connected between a first semiconductor device driven by a first supply voltage having a first difference from a reference voltage and a second semiconductor device driven by a second supply voltage having a second difference, less than the first difference, from the reference voltage, and the signal level shifting bus switch comprising:
a first terminal configured to input/output the first supply voltage;
a second terminal configured to input/output the second supply voltage;
a control terminal configure to receive a control voltage;
a first transistor with a gate driven by a control signal of the first supply voltage;
a second transistor with a gate driven by a control signal of the second supply voltage, the first and second transistors being connected between the first and second terminals; and
an absolute value of a threshold voltage of the second transistor being less than an absolute value of a threshold voltage of the first transistor.

2. The signal level shifting bus switch of claim 1,
wherein the first supply voltage, which is inputted/outputted through the first I/O terminal, is higher than the reference voltage; the second supply voltage, which is inputted/outputted through the second I/O terminal, has a voltage value between the reference voltage and the first supply voltage, the first transistor is an n-channel transistor with a gate driven by a signal of the first supply voltage, and the second transistor is an n-channel transistor with a gate driven by a signal of the second supply voltage.

3. The signal level shifting bus switch of claim 2,
wherein the threshold voltage of the second transistor of the n-channel transistor is set at 0V.

4. The signal level shifting bus switch of claim 2,
wherein the reference voltage is at 0V, the first supply voltage is at 5V, and the second supply voltage is at one of 3.3V and 2.5V.

5. The signal level shifting bus switch of claim 2,
wherein the reference voltage is at 0V; the first supply voltage has a high voltage level of 5V; and the second supply voltage has a middle voltage level of 3.3V.

6. The signal level shifting bus switch of claim 2,
wherein the reference voltage is at 0V; the first supply voltage has a high voltage level of 5V; and the second supply voltage has a low voltage level of 2.5V.

7. The signal level shifting bus switch of claim 2,
wherein the first transistor is of the enhancement type having a predetermined threshold; and the second transistor is of the intrinsic type having a threshold value of zero.

8. The signal level shifting bus switch of claim 1,
wherein the first supply voltage which is inputted/outputted through the first terminal is lower than the reference voltage; the second supply voltage which is inputted/outputted through the second terminal has a voltage value between the reference voltage and the first supply voltage; the first transistor is a p-channel transistor with a gate driven by a signal of the first supply voltage; and the second transistor is a p-channel transistor with a gate driven by a signal of the second supply voltage.

9. The signal level shifting bus switch of claim 8,
wherein the threshold voltage of the second transistor of the p-channel transistor is set at 0V.

10. The signal level shifting bus switch of claim 8,
wherein a voltage level of the control signal fed to the common terminal is a low voltage level that is a voltage level of the first supply voltage.

11. The signal level shifting bus switch of claim 8
wherein the reference voltage is at 0V, the first supply voltage is at −5V, and the second supply voltage is at anyone of −3.3V and −2.5V.

12. The signal level shifting bus switch of claim 8,
wherein the reference voltage is at 0V; the first supply voltage has a low voltage level of −5V; and the second supply voltage has a middle voltage level of −3.3V.

13. The signal level shifting bus switch of claim 8,
wherein the reference voltage is at 0V; the first supply voltage has a low voltage level of −5V; and the second supply voltage has a high voltage level of −2.5V.
